(19) United States
(12) Patent Application Publication
(10) Pub. No.: US 2010/0272142 A1
(43) Pub. Date: Oct. 28, 2010

(54) Nitride semiconductor optical element and method of manufacturing the same

(75) Inventor: Kazuhisa Fukuda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki-shi (JP)

(21) Appl. No.: 12/662,185

(22) Filed: Apr. 5, 2010

(30) Foreign Application Priority Data
Apr. 27, 2009 (JP) 2009-108164

(51) Int. Cl. H01S 5/02; H01L 33/00

(52) U.S. Cl. 372/45.01; 438/46; 257/E33.005

(57) ABSTRACT

Provided is a semiconductor laser element having a first protective film provided at least over the light emitting end face of an active layer (3-period multiple quantum well (MQW) active layer); and a second protective film provided over the first protective film, wherein, the first protective film is provided between a semiconductor which composes the light emitting end face and the second protective film, and a portion of the first protective film, brought into direct contact with the semiconductor, is mainly composed of a rutile-structured TiO₂ film.

This application is based on Japanese patent application No. 2009-108164 the content of which is incorporated hereinto by reference.

### BACKGROUND

1. Technical Field

The present invention relates to a nitride semiconductor optical element, and a method of manufacturing the same.

2. Related Art

Group-III nitride semiconductor represented by gallium nitride has attracted a good deal of attention as a material for composing light emitting diode (LED) and laser diode (LD), by virtue of blue-purple light efficiently obtainable therefrom. Among others, LD is fully expected as a light source for large-capacity optical disk drive. In recent years, high-output LD has extensively been investigated, aiming at providing a light source for writing.

Japanese Laid-Open Patent Publication No. 2007-59897 describes a gallium nitride semiconductor laser element having a dielectric film formed on the light emitting end faces. The gallium nitride semiconductor laser element has, as illustrated in FIG. 6, an n-type nitride semiconductor layer 200, an active layer 205, and a p-type nitride semiconductor layer 210, as nitride semiconductor layers, stacked in this order on a substrate 100, wherein the substrate 100 and the nitride semiconductor layers are arranged so as to align the cleavage surfaces thereof nearly on the same plane. The light emitting end face has a Al₂O₃ film formed thereon as a dielectric film.

As described in the above, as an end face protective film of the 405-nm blue-purple semiconductor laser element, a low-reflectivity (anti-reflective) film (referred to as “AR film”, hereinafter) consisted of an Al₂O₃ single film has been used typically on the light emitting end face. The Publication describes that the critical optical output level causative of catastrophic optical damage (COD) may be elevated, and thereby high-output operation may be ensured.

However, formation of the Al₂O₃ film on the AR film side has been known to allow reaction between the semiconductor and the Al₂O₃ film to proceed during consecutive operation of the laser element, and this has been understood as one reason of degradation in reliability of the laser element. For the purpose of suppressing the interfacial reaction, Japanese Laid-Open Patent Publication No. 2007-59897 proposes a method of forming a single-crystalline Al₂O₃ film as a reaction-preventive layer.

Japanese Laid-Open Patent Publication No. 2006-186228 describes a semiconductor laser element, having an Al₂O₃ film formed as an optical film on the light emitting end face. As illustrated in FIG. 7, a semiconductor laser element 20 has an optical film 16 consisted of Al₂O₃ and formed on the light emitting end face, and has a photo-catalytic layer 17 composed of TiO_{2-X}N_{X} and formed further thereon.

The Publication describes that the exposed photo-catalytic layer 17 oxidatively decomposes organic substances 29 in the semiconductor laser element 20. Accordingly, it is reportedly possible to suppress the organic substances from adhering on the end face of the semiconductor laser element.

However, the above techniques described in these Publications have been suffering from a problem of the reaction between the semiconductor and Al₂O₃, which results in COD.

### SUMMARY

The present inventors made extensive investigations into materials for composing the film, and conditions for forming the film relevant to a method of suppressing the interfacial reaction with semiconductor, and found it effective to form a TiO₂ film so as to directly contact with the end face of the semiconductor.

TiO₂ has conventionally been considered as being inappropriate, unlike Al₂O₃ or the like, as a material to be formed in direct contact with the light emitting end face of the nitride semiconductor laser element, because TiO₂ has a band gap energy close to the energy of laser light, and shows increase in absorption in the visible light region or electro-conductivity due to presence of defects (impurity, vacancy, and so forth) in the film.

However, contrary to the prediction, the present inventors found out that TiO₂ can successfully suppress the interfacial reaction with the semiconductor.

Further investigations by the present inventors revealed that the reliability of the TiO₂ film formed on the end face is closely related to the structures (rutile, anatase, amorphous) of TiO₂. The present inventors also found out that appropriate control and combination of the individual structures makes it possible to ensure a high COD level even under a long period of operation.

According to the present invention, there is provided

A nitride semiconductor optical element comprising:

a substrate;

an active layer composed of a Group-III nitride semiconductor which contains Ga as a constitutive element, and provided over said substrate, which includes:

a first protective film which is provided at least over an light emitting end face of the active layer; and

a second protective film provided over the first protective film,

the first protective film being brought into contact with the semiconductor which composes the light emitting end face, and

a portion of the first protective film brought into contact with the semiconductor being composed of a rutile-structured TiO₂ film.

According to the present invention, there is also provided a method of manufacturing a nitride semiconductor optical element, which includes:

forming, on a substrate, a stacked structure having an active layer composed of a Group-III nitride semiconductor which contains Ga as a constitutive element; and

providing a first protective film and a second protective film at least over the light emitting end face of the active layer,

the first protective film being provided so as to be brought into contact with the semiconductor which composes the light emitting end face, and

a portion of the first protective film brought into contact with semiconductor being composed of a rutile-structured TiO₂ film.

In the semiconductor laser element of this embodiment, the first protective film is provided between the semiconductor and the second protective film, while allowing the rutile-structured TiO₂ film to directly contact with the semiconductor which composes the light emitting end face. By virtue of this configuration, the semiconductor and the second protective film may be suppressed from reacting with each other, and thereby the COD level may be suppressed from degrading.

According to the present invention, a highly-reliable nitride semiconductor laser element may be provided.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are sectional views schematically illustrating a structure of a semiconductor laser element according to an embodiment of the present invention;

FIGS. 2A to 2C, FIG. 3A to 3C, and FIGS. 4A and 4B are sectional views illustrating procedures of manufacturing the semiconductor laser element according to the embodiment of the present invention;

FIG. 5 is a drawing illustrating time-dependent changes in COD levels of the semiconductor laser elements according to embodiments of the present invention; and

FIG. 6 and FIG. 7 are sectional views illustrating structures of conventional semiconductor laser elements.

### DETAILED DESCRIPTION

The invention will now be described herein with reference to illustrative embodiments. Those skilled in the art will recognize that many alternative embodiments can be accomplished using the teachings of the present invention and that the invention is not limited to the embodiments illustrated for explanatory purposes.

Embodiments of the present invention will be explained below, referring to the attached drawings. Note that any similar constituents in all drawings will given similar reference numerals or symbols, and explanations therefor will not always be repeated.

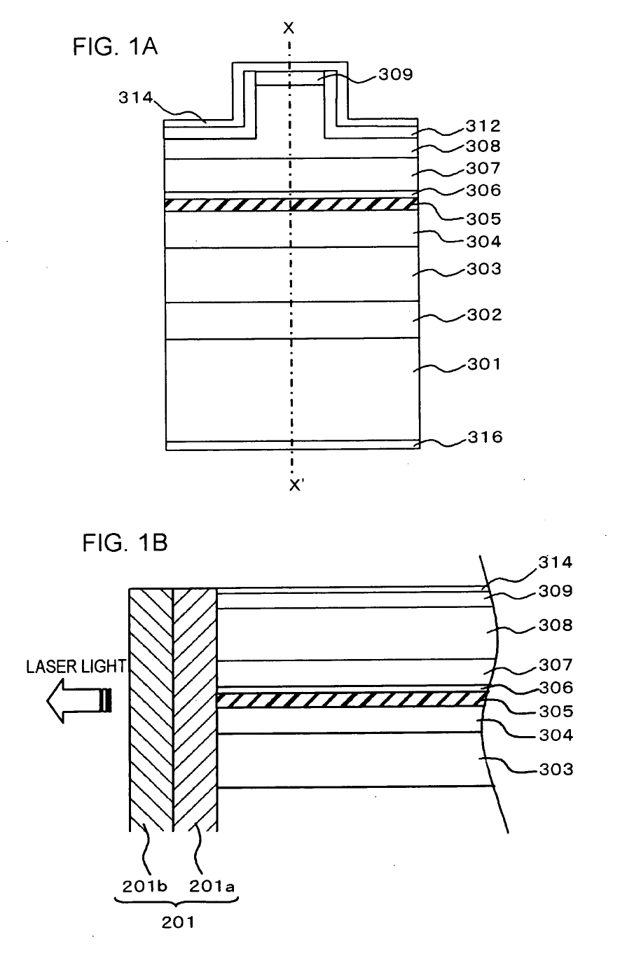

A semiconductor laser element according to an embodiment of the present invention will be explained, referring to FIGS. 1A and 1B.

FIG. 1A is a schematic drawing of a structure of the element as viewed in the direction normal to the longitudinal direction of the oscillator, and FIG. 1B is a sectional view taken along line X-X′ in FIG. 1A, in parallel with the longitudinal direction of oscillator, enlarging a portion in the vicinity of the emission end face.

The semiconductor laser element of this embodiment is a nitride semiconductor optical element having an active layer (3-period multiple quantum well (MQW) active layer 305) composed of a Group-III nitride semiconductor which contains Ga as a constitutive element, and is configured to emit laser light from the end face of the active layer. The semiconductor laser element has a first protective film 201a provided at least over the light emitting end face of the active layer (3-period multiple quantum well (MQW) active layer 305), and a second protective film 201b provided over the first protective film 201a. The first protective film 201a is provided between a semiconductor which composes the light emitting end face and the second protective film 201b, and a portion of the first protective film 201a, brought into direct contact with the semiconductor, is mainly composed of a rutile-structured TiO₂ film.

As illustrated in FIG. 1A, the semiconductor laser element of this embodiment has a Si-doped, n-type GaN layer 302 (Si concentration=4×10¹⁷ cm⁻³, 1 μm thick), an n-type cladding layer 303 composed of Si-doped, n-type Al_{0.1}Ga_{0.9}N (Si concentration=4×10¹⁷ cm⁻³, 2 μm thick), an n-type GaN light confinement layer 304 composed of Si-doped, n-type GaN (Si concentration=4×10¹⁷ cm⁻³, 0.1 μm thick), a 3-period multiple quantum well (MQW) active layer 305 composed of In_{0.15}Ga_{0.85}N (3 nm thick) well layers and Si-doped In_{0.01}Ga_{0.99}N (Si concentration=1×10¹⁸ cm⁻³, 4 nm thick) barrier layers, a capping layer 306 composed of Mg-doped, p-type Al_{0.2}Ga_{0.8}N (Mg concentration=2×10¹⁹ cm⁻³, 10 nm thick), a p-type GaN light confinement layer 307 composed of Mg-doped, p-type GaN (Mg concentration=2×10¹⁹ cm⁻³, 0.1 μm thick), a p-type Al_{0.1}Ga_{0.9}N cladding layer 308, and a p-type GaN contact layer 309 composed of Mg-doped, p-type GaN (Mg concentration=1×10²⁰ cm⁻³, 0.02 μm thick), all of which are stacked on an n-type GaN substrate 301. The p-type cladding layer 308 and the p-type contact layer 309 configure a ridge structure formed by dry etching into a stripe pattern. A p-type electrode 314 is provided over the top surface of the p-type contact layer 309 which is positioned on the top of the ridge, and an n-type electrode 316 is provided on the lower surface of the n-type GaN substrate 301. Over the end faces of the oscillator formed by cleavage, there are provided dielectric protective films.

As the dielectric protective films herein, an AR film 201 is formed on the laser emission end face, and an HR (high-reflection) film (not illustrated) is formed on the opposite end face.

The AR film 201 illustrated in FIG. 1B is composed of a multi-layered dielectric film. In this embodiment, the AR film 201 has the first protective film 201a and the second protective film 201b. The first protective film 201a is brought into direct contact with the semiconductor which composes the light emitting end face. The first protective film 201a has a rutile-structured TiO₂ film which is brought into direct contact with the semiconductor. In other words, the first protective film 201a is provided between the semiconductor and the second protective film 201b. By virtue of this configuration, the semiconductor and the second protective film 201b may be suppressed from reacting with each other, and thereby the COD level may be suppressed from degrading, even under high-output laser operation. In particular, by forming a rutile structure, which is the most stable form of TiO₂, at the interface with the semiconductor where optical density is maximized, changes in volume of the TiO₂ film in association with phase changes induced by the laser light, light absorption ascribable to defects in the film, degradation of reliability induced by leakage current and so forth, may be suppressed. The first protective film 201a, having the rutile-structured TiO₂ film, may therefore be understood as a reaction-suppressive film which suppresses the semiconductor and the second protective film 201b from reacting with each other.

The first protective film 201a is not specifically limited, so far as it is formed to have the rutile-structured TiO₂ film in a portion of the first protective film 201a brought into direct contact with the semiconductor. For example, the first protective film 201a may be such as having a rutile-structured TiO₂ film and an amorphous TiO₂ film formed in this order as viewed from the semiconductor side. The amorphous TiO₂ in this case functions as a buffer layer. In other words, by forming the rutile-structured TiO₂ film and the second protective film 201b, while placing the amorphous TiO₂ film in between, separation of the films, ascribable to difference in thermal expansion coefficient between the rutile-structured TiO₂ film formed at the interface with the semiconductor and the second protective film 201b formed on the surface side, or ascribable to deformation of the second protective film 201b, may be suppressed.

In a more preferable example, the first protective film 201a is configured to have an amorphous TiO₂ film held between the rutile-structured TiO₂ films from both sides thereof. In other words, the rutile-structured TiO₂ film, the amorphous TiO₂ film, and the rutile-structured TiO₂ film are formed in this order as viewed from the semiconductor side. By virtue of this configuration, increase in absorption or leakage current, which are induced typically by damages possibly applied to the first protective film 201a in the process of forming the second protective film 201b, may be suppressed.

In the first protective film 201a, the thickness of the rutile-structured TiO₂ film, which is brought into direct contact with the semiconductor, is preferably adjusted to 5 nm or larger and 50 nm or smaller. By adjusting the thickness to 50 nm or smaller, separation of the films, inducible by stress, may be suppressed. On the other hand, by adjusting the thickness to 5 nm or larger, controllability of the thickness of film in the process of formation, or the suppressive effect on the interfacial reaction with the semiconductor, may be suppressed from degrading.

The second protective film 201b may be selectable from dielectric materials without special limitation, and may preferably selectable from those having refractive indices smaller than that of TiO₂ (refractive index=2.6), such as Al₂O₃ (refractive index=1.7) and SiO₂ (refractive index=1.4). By combining these materials, the AR film 201 composed of the first protective film 201a and the second protective film 201b may preferably be controlled in the reflectivity. For example, by adjusting the refractive index of the second protective film 201b smaller than that of the first protective film 201a, an appropriate reflectivity may be obtained. The same will apply also to the case where the AR film 201 is composed of three or more films, wherein an appropriate reflectivity may be obtained by adjusting the refractive indices and thicknesses of the individual films.

The AR film 201 (mirror film) has an end face reflectivity to laser light preferably adjusted to 1 to 30% (in the following description, every range expressed using “to” is defined to contain the numerals placed before and after “to”, as the upper and lower limit values, respectively, unless otherwise specifically noted).

On the other hand, the HR film is composed of a multi-layered film configured to combine a low-refractive-index dielectric film and a high-refractive-index dielectric film. The HR film is preferably adjusted to have a reflectivity with respect to laser light of 70 to 99%.

The AR film 201 and the HR film may be formed typically by sputtering or vapor evaporation. As materials composing the AR film 201 and the HR film, oxides such as Al₂O₃, SiO₂, TiO₂, ZrO₂, Ta₂O₅ and Nb₂O₅; fluorides such as MgF₂ and CaF₂; and nitrides such as AlN and Si₃N₄ may be adoptable. These materials may be combined while appropriately adjusting the refractive indices and thicknesses. In this way, the AR film 201 and the HR film may be formed in a stable manner. Also extraction efficiency of laser light may be improved, enough to allow high-output operation of the laser element.

Next, operations and effects of the semiconductor laser element of this embodiment will be explained.

In the semiconductor laser element of this embodiment, the first protective film 201a is provided between the semiconductor and the second protective film 201b, while allowing the rutile-structured TiO₂ film to directly contact with the semiconductor. By virtue of this configuration, the semiconductor and the second protective film 201b may be suppressed from reacting with each other, and thereby the COD level may be suppressed from degrading. As a consequence, the semiconductor laser element having higher output, longer service life and improved reliability may be provided.

In addition to the above-described configuration, the semiconductor laser element of this embodiment has an amorphous TiO₂ film provided between the rutile-structured TiO₂ film and the second protective film 201b. By the contribution of the amorphous TiO₂ film, separation of films ascribable to difference in thermal expansion coefficient between the rutile-structured TiO₂ film and the second protective film 201b, or ascribable to deformation of the second protective film 201b, may be suppressed. As a consequence, the semiconductor laser element having higher output, longer service life and improved reliability may be provided.

In addition to the above-described configuration, the semiconductor laser element of this embodiment has a rutile-structured TiO₂ film provided between the amorphous TiO₂ and the second protective film 201b. By the contribution of this configuration, increase in absorption or leakage current, which are induced typically by damages possibly applied to the first protective film 201a in the process of forming the second protective film 201b, may be suppressed. As a consequence, the semiconductor laser element having higher output, longer service life and improved reliability may be provided.

Next, the effects of this embodiment will further be explained, in comparison with the prior art.

According to the aforementioned Japanese Laid-Open Patent Publication No. 2007-59897, the single-crystalline Al₂O₃ film is formed as a reaction protective layer over the light emitting end face, using an ECR sputtering apparatus. Use of the ECR sputtering apparatus is disadvantageous in terms of low productivity and high cost of introduction. Moreover, it has been difficult to form the single-crystalline Al₂O₃ film by using an RF (Radio Frequency) sputtering apparatus.

In contrast, according to the present invention, the rutile-structured TiO₂ film, the amorphous TiO₂ film and the Al₂O₃ film may be formed over the light emitting end face, typically by using an RF sputtering apparatus. As described in the above, an apparatus excellent in productivity and low in cost for introduction, such as RF sputtering apparatus, may be adoptable.

This embodiment allows various modifications.

For example, the HR film may be composed of a multi-layered dielectric film, without special limitation. The multi-layered dielectric film may have the same pattern with the AR film 201, or may have a different pattern. The HR film having the same pattern may concomitantly be formed with the AR film 201.

The portion of the first protective film 201a, which is brought into direct contact with the semiconductor, may be configured solely by the rutile-structured TiO₂ film. The rutile-structured TiO₂ film in this case may be allowed to contain carbon component, nitrogen component and so forth, so far as the contents thereof are inevitable as a result of the manufacturing process, or equivalent thereto. The rutile-structured TiO₂ film may contain carbon component, nitrogen component and so forth, which are introduced thereinto in a time-dependent manner, as a result of operation of the semiconductor laser element.

Although the second protective film 201b in this embodiment is configured typically by using Al₂O₃, the reaction between the semiconductor and the second protective film 201b may be suppressed also by using the above-described materials other than Al₂O₃.

### EXAMPLES

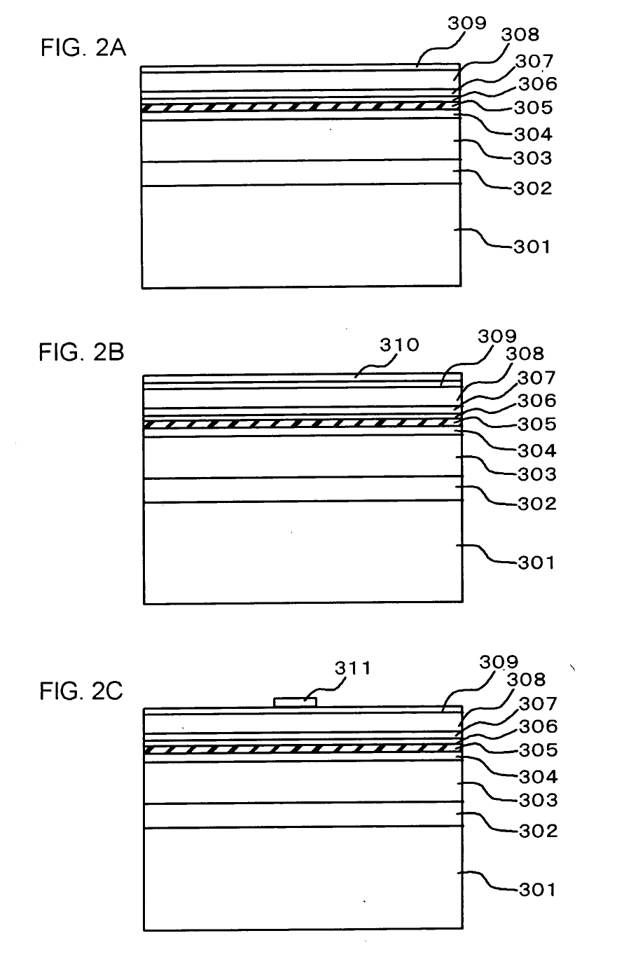

In this Example, a ridge stripe laser element will be described as an exemplary semiconductor laser element according to this embodiment. A method of manufacturing the semiconductor laser element of this embodiment will be explained below, referring to FIGS. 2A to 2C, FIG. 3A to 3C and FIGS. 4A and 4B.

FIGS. 2A to 2C, FIG. 3A to 3C and FIGS. 4A and 4B are sectional views illustrating procedures of manufacturing the semiconductor laser element of this embodiment.

In this process, an n-type GaN (0001) substrate was used as the substrate. The element structure was formed by using a low-pressure MOVPE apparatus adjustable at 300 hPa. A mixed gas of hydrogen and nitrogen was used as a carrier gas. Trimethyl gallium (TMG), trimethyl aluminum (TMA), and trimethyl indium (TMI) were used as Ga, Al and In sources, respectively. Silane (SiH₄) was used as an n-type dopant, and bis(cyclopentadienyl) magnesium (Cp₂Mg) was used as a p-type dopant.

First, the n-type GaN substrate 301 was placed in the growth apparatus, the substrate was heated under supply of NH₃, and the growth was started after a predetermined growth temperature was reached. The Si-doped, n-type GaN layer 302 (Si concentration=4×10¹⁷ cm⁻³, 1 μm thick), the n-type cladding layer 303 composed of Si-doped, n-type Al_{0.1}Ga_{0.9}N (Si concentration=4×10¹⁷ cm⁻³, 2 μm thick), the n-type light confinement layer 304 composed of Si-doped, n-type GaN layer (Si concentration=4×10¹⁷ cm⁻³, 0.1 μm thick), the 3-period multiple quantum well (MQW) active layer 305 composed of In_{0.15}Ga_{0.85}N (3 nm thick) well layers and Si-doped In_{0.01}Ga_{0.99}N (Si concentration=1×10¹⁸ cm⁻³, 4 nm thick) barrier layers, the capping layer 306 composed of Mg-doped, p-type Al_{0.2}Ga_{0.9}N (Mg concentration=2×10¹⁹ cm⁻³, thick 10 nm), and the p-type light confinement layer 307 composed of Mg-doped, p-type GaN (Mg concentration=2×10¹⁹ cm⁻³, 0.1 μm thick) were sequentially deposited. In succession, the p-type cladding layer 308 composed of Mg-doped, p-type Al_{0.1}Ga_{0.9}N (Mg concentration=1×10¹⁹ cm⁻³, 0.5 μm thick) was deposited, and the contact layer 309 composed of Mg-doped, p-type GaN (Mg concentration=1×10²⁰ cm⁻³, 20 nm thick) was further deposited (FIG. 2A).

GaN in this process was grown under conditions which include a substrate temperature of 1080° C., a rate of TMG supply of 58 μmol/min, and a rate of NH₃ supply of 0.36 mol/min. AlGaN was grown under conditions which include a substrate temperature of 1080° C., a rate of TMA supply of 36 μmol/min, a rate of TMG supply of 58 μmol/min, and a rate of NH₃ supply of 0.36 mol/min. The InGaN MQW was grown under conditions which include a substrate temperature of 800° C., a rate of TMG supply of 8 μmol/min, and a rate of NH₃ supply of 0.36 mol/min, wherein the well layers were grown at a rate of TMI supply of 48 μmol/min, and the barrier layers were grown at a rate of TMI supply of 3 μmol/min.

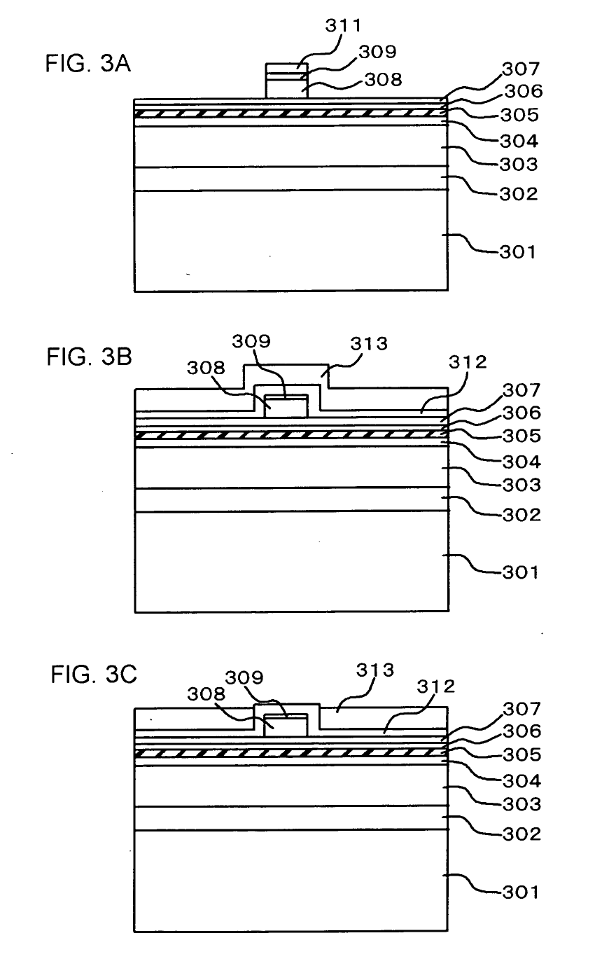

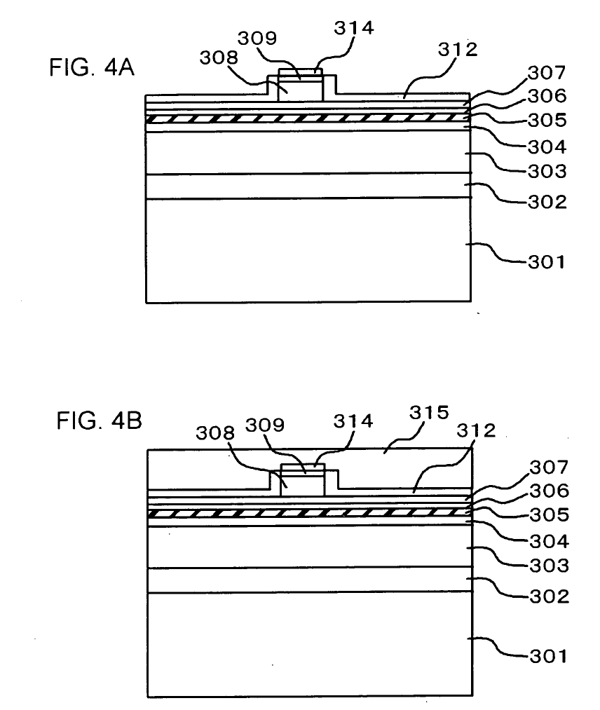

A SiO₂ layer 310 was formed over the thus-fabricated wafer for forming the laser element (FIG. 2B), and then processed by lithography and etching to give a SiO₂ stripe 311 of 1.3 μm wide (FIG. 2C). The p-type cladding layer 308 was partially removed by dry etching using the SiO₂ stripe 311 as a mask, to thereby form the ridge structure (FIG. 3A). The SiO₂ mask 311 was then removed, and an SiO₂ layer 312 was newly deposited over the entire surface of the wafer. A resist 313 is coated thereon to a sufficient thickness (FIG. 3B), and then etched back in an oxygen plasma to thereby expose the top surface of the ridge (FIG. 3C). A portion of the SiO₂ 312 on the top surface of the ridge is then removed using a buffered hydrofluoric acid solution, a Pd/Pt film is deposited by electron beam evaporation, and a p-contact (p-electrode 314) was formed by liftoff process (FIG. 4A). Next, the product was subjected to Rapid thermal anneal (RTA) in a nitrogen atmosphere at 600° C. for 30 seconds, to thereby form a p-ohmic electrode. A Ti film of 50 nm thick, a Pt film of 100 nm thick, and an Au film of 2 μm were deposited by sputtering, to thereby form a cover electrode 315 (FIG. 4B). On the other hand, after formation of the p-electrode, the back surface of the wafer was polished to thereby thin the wafer down to a thickness of 100 μm, a Ti film (5 nm), an Al film (20 nm), a Ti film (10 nm), and an Au film (500 nm) were formed in this order by vacuum evaporation, to thereby form an unillustrated n-electrode. The wafer having the electrodes formed thereon was cleaved in the direction vertical to the longitudinal direction of the stripe, to thereby form a laser bar having a length of oscillator of 600 μm.

Next, the process for forming the protective film over the thus-fabricated end face of oscillator will be detailed. For the protective film, a dielectric film formed by vapor evaporation, sputtering or the like may be used.

First, the AR film 201 having a reflectivity of 0.1 to 22% was formed over one laser emission end face. Next, an HR film having a reflectivity of 90% or larger was formed on the opposite end face. An RF magnetron sputtering apparatus was used in these processes.

Structure of the TiO₂ film formed by sputtering may be controlled by adjusting conditions including supplied power, pressure, and additive gas. The present inventors confirmed from X-ray diffractometry (XRD) of the TiO₂ film formed on a sapphire substrate, that three types of structures, which are rutile, anatase and amorphous, may be obtained by appropriately selecting the conditions.

In this study of determining the conditions for forming the films, the present inventors confirmed the rutile structure of the TiO₂ film by the procedures (1) to (3) below.

(1) A single film is formed on the sapphire substrate, and is measured by XRD (θ-2θ scanning).

(2) An intense diffraction peak ascribable to the substrate (Al₂O₃ (0006)) is confirmed at around 2θ=41.7°.

(3) The rutile structure is determined based on differences described in (i) to (iii) below:

(i) those showing peaks at around 2θ=39.2° and 36.1° may be identified to have the rutile structure (rutile (200), (101));

(ii) those showing peaks at around 2θ=38.6° may be identified to have the anatase structure (anatase (112)); and

(iii) those showing no peak other than the peak ascribable to the substrate may be identified to have the amorphous structure.

(The substrate herein may have any type of crystal, so far as it has a crystalline structure.)

Exemplary conditions for forming the individual protective films will be shown below.

Targets to be sputtered were 4-inch, high-impurity ones composed of TiO₂ and Al₂O₃. The films were formed under fixed conditions including a substrate temperature of 200° C., and an Ar flow rate of sccm.

### (Conditions for Forming TiO₂ Film)

rutile-structured film: 0.5 sccm of oxygen added, pressure=1.4 Pa, RF power=0.8 kW

anatase-structured film: pressure=1.4 Pa, RF power=0.2 kW

amorphous film: pressure=3.3 Pa, RF power=0.2 kW

### (Formation of Al₂O₃ Film)

pressure=1.4 Pa, RF power=0.6 kW

Treatment such as baking, UV/ozone cleaning, plasma cleaning were carried out, for the purpose of preventing organic substances from adhering to the end faces.

After the first protective film 201a mainly composed of the rutile-structured TiO₂ film was formed as described in the above, the second protective film 201b mainly composed of Al₂O₃ was formed. The AR film 201, which has the TiO₂ film brought into direct contact with the semiconductor which composes the light emitting end face, was formed in this way. The laser bar having the AR film 201 formed thereon was once taken out from the sputtering apparatus, then placed again in the sputtering apparatus, and the HR film composed of an SiO₂/TiO₂ multi-layered film, and having a reflectivity of 90%, was formed over the opposite end face. The laser bar was then separated to produce a plurality of laser chips of 300 μm wide.

Each laser chip obtained by the above-described process was bonded to a heat sink, to thereby obtain a nitride semiconductor laser element (FIG. 1A).

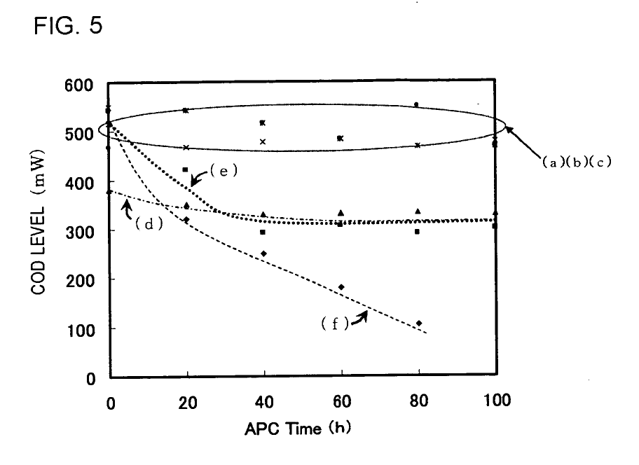

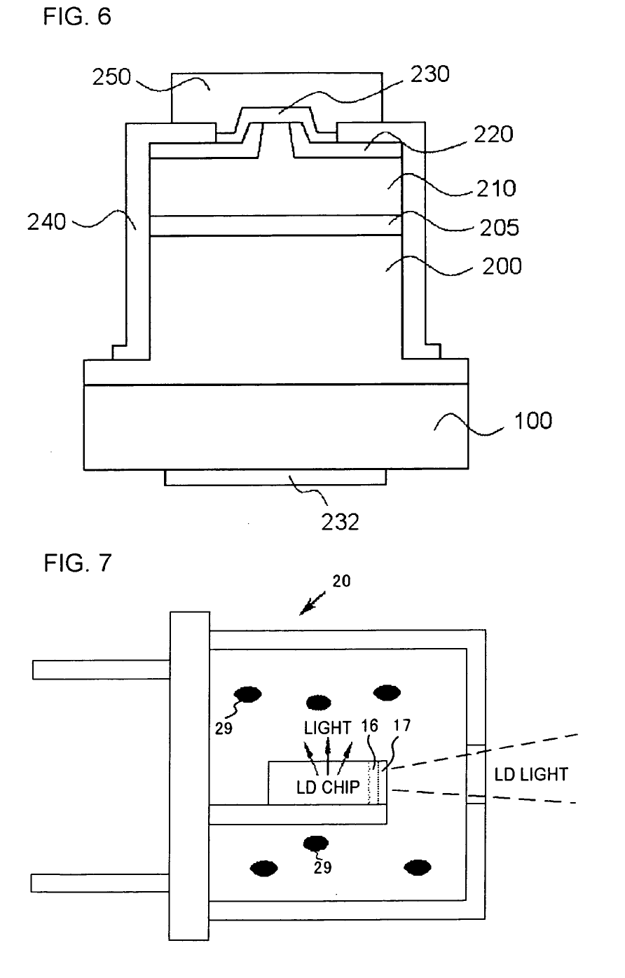

Next, the thus-obtained semiconductor element of this embodiment was subjected to evaluation of COD level, and cross-sectional TEM observation of the portion in the vicinity of the AR-deposited end face. FIG. 5 illustrates results of evaluation of COD level.

In the evaluation of COD level, the semiconductor element was subjected to Advanced Process Control (APC) test at 80° C., using 100-mW pulse (width=50 ns, duty=50%), and the COD level was measured every 20 hours. In the cross-sectional TEM observation, a cross-section of the semiconductor element, after being operated for 100 hours, taken in the vicinity of AR-deposited end face, was observed.

In Examples and Comparative Examples, the AR films listed below were formed. The thicknesses d1 and d2 of the first protective film 201a (TiO₂) and the second protective film 201b (Al₂O₃) were given as d1=38 nm and d2=24 nm, respectively, and the reflectivity was adjusted to 15%.

### Example 1

(a) rutile-structured TiO₂/Al₂O₃

### Example 2

(b) rutile-structured TiO₂ (5 nm)/amorphous TiO₂ (33 nm)/Al₂O₃

### Example 3

(c) rutile-structured TiO₂ (5 nm)/amorphous TiO₂ (28 nm)/rutile-structured TiO₂ (5 nm)/Al₂O₃

### Referential Example 1

(d) anatase-structured TiO₂/Al₂O₃

### Referential Example 2

(e) amorphous TiO₂/Al₂O₃

### Comparative Example 1

(f) Al₂O₃ single film (100 nm)

Results of the evaluation of COD level, illustrated in FIG. 5, will be explained. Indications (a) to (f) in FIG. 5 correspond to the individual AR films. More specifically, asterisk plots represent (a), cross plots represent (b), circle plots represent (c), triangle plots represent (d), square plots represent (e), and rhombic plots represent (f).

The AR films represented by plots (a) to (c), having the rutile-structured TiO₂ films formed at the interfaces with the semiconductor, show no decrease in the COD level. The AR films represented by plots (d) and (e), respectively having the anatase-structured TiO₂ film and the amorphous TiO₂ film formed at the interfaces with the semiconductor, show decrease in the COD level in the early stages, followed by suppressed rates of decrease in the COD level after the elapse of certain lengths of period.

On the other hand, the AR film represented by plot (f), composed of the Al₂O₃ single film, shows a high COD level in the early stage, but followed by decrease in the COD level with APC time, unlike those represented by plots (a) to (c). Unlike those represented by plots (d) and (e), suppression of the rate of decrease in the COD level was not observed.

Next, results of the TEM observation will be explained.

From the observation of the cross-sections, the AR films represented by plots (a) to (e) were confirmed to maintain clear boundaries between the semiconductor and the TiO₂ films. On the other hand, the AR film represented by plot (f) was confirmed to cause therein reaction between Al₂O₃ and semiconductor.

The AR films (a) to (c) were also subjected to APC test at 80° C., but at a light output of exceeding 200 mW. From comparison between the AR films (c) and (a), the AR film (c) was found to show no fluctuation in the operational current. From cross-sectional TEM observation of degraded elements, the AR film (c) was found to be highly reliable, because there was no separation observed at the semiconductor/TiO₂ interface. On the other hand, from comparison between the AR films (c) and (b), both of the AR films (c) and (b) were found to cause no fluctuation in the operational current, unlike the AR film. The AR film (c) was found to cause no COD even on the end faces of a part of degraded elements, and was therefore proven to be highly reliable. Stable operation over 1000 hours was confirmed for all elements provided with the AR film (c).

From these results, it was confirmed that, in the semiconductor laser elements having the TiO₂ films formed in direct contact with the semiconductor on the AR side, the reaction at the interface between the semiconductor and the AR film, which may possibly be induced by laser light under high-output operation, may successfully be suppressed. It was also supposed that, for the case where the TiO₂ film, which is brought into direct contact with the semiconductor, has the anatase structure, the initial COD level is low because of increase in absorption of visible light contributed by impurities such as nitrogen and carbon. It was also supposed that, for the case where the TiO₂ film has the amorphous structure, the COD level again decreases because phase change to anatase may proceed while being induced by laser light. For the case where the amorphous TiO₂ film was used, a problem of lowering in the COD level was solved supposedly because the rutile-structured TiO₂ film, which is the most stable form of TiO₂, was provided at the interface with the semiconductor where optical density is largest. For the case where the TiO₂/Al₂O₃ double-layered structure was used, it was found that the separation of films, which is ascribable to difference in thermal expansion coefficient between the Al₂O₃ film and the rutile-structured TiO₂ film, or ascribable to deformation of the Al₂O₃ film, may be suppressed by providing the amorphous TiO₂ film at the interface with the semiconductor as a buffer layer. It was also supposed that degradation in the COD level, presumed as being ascribable to damage possibly given in the process of formation of the Al₂O₃ film, was suppressed, by providing the rutile-structured TiO₂ film also at the interface with the Al₂O₃ film.

Of course, it is to be understood that the above-described embodiments and a plurality of modifications may be combined, so far as no contradiction arises among them. The structures of the individual portions specifically described in the embodiments and modifications may be modified in various ways, so far as the present invention may be satisfied.

It is apparent that the present invention is not limited to the above embodiments, that may be modified and changed without departing from the scope and spirit of the invention.

What is claimed is:

1. A nitride semiconductor optical element comprising:
a substrate;
an active layer composed of a Group-III nitride semiconductor which contains Ga as a constitutive element, and provided over said substrate;
a first protective film which is provided at least over an light emitting end face of said active layer; and
a second protective film provided over said first protective film,
said first protective film being brought into contact with the semiconductor which composes said light emitting end face, and
a portion of said first protective film brought into contact with said semiconductor being composed of a rutile-structured TiO₂ film.

2. The nitride semiconductor optical element as claimed in claim 1,
wherein in said first protective film, said rutile-structured TiO₂ film and a buffer film are provided in this order as viewed from said semiconductor.

3. The nitride semiconductor optical element as claimed in claim 1,
wherein said first protective film is configured so that a buffer film is held between said rutile-structured TiO₂ films from both sides thereof, and
said rutile-structured TiO₂ films being respectively provided to a portion in contact with said semiconductor, and to a portion in contact with said second protective film.

4. The nitride semiconductor optical element as claimed in claim 2,
wherein said buffer film contains an amorphous TiO₂ film.

5. The nitride semiconductor optical element as claimed in claim 1,
wherein said second protective film has a refractive index smaller than that of said first protective film.

6. The nitride semiconductor optical element as claimed in claim 1,
wherein said second protective film contains Al₂O₃.

7. A method of manufacturing a nitride semiconductor optical element, comprising:
forming, on a substrate, a stacked structure having an active layer composed of a Group-III nitride semiconductor which contains Ga as a constitutive element; and
providing a first protective film and a second protective film at least over the light emitting end face of said active layer,
said first protective film being provided so as to be brought into contact with the semiconductor which composes said light emitting end face, and
a portion of said first protective film brought into contact with semiconductor being composed of a rutile-structured TiO₂ film.
